(19) United States
(12) Patent Application Publication
(10) Pub. No.: US 2013/0278842 A1
(43) Pub. Date: Oct. 24, 2013

(54) TELEVISION RECEPTION APPARATUS, MODULE, AND ELECTRONIC APPARATUS

(71) Applicant: KABUSHIKI KAISHA TOSHIBA, Tokyo (JP)

(72) Inventors: Kota TOKUDA, Kawasaki-shi (JP); Nobuhiro YAMAMOTO, Yokohama-shi (JP); Tsuyoshi KOZAI, Ome-shi (JP)

(73) Assignee: KABUSHIKI KAISHA TOSHIBA, Tokyo (JP)

(21) Appl. No.: 13/735,194

(22) Filed: Jan. 7, 2013

(30) Foreign Application Priority Data
Apr. 24, 2012 (JP) 2012-099182

(51) Int. Cl. H04N 5/64; H05K 1/02

(52) U.S. Cl. CPC H04N 5/64; H05K 1/0204; H05K 1/02
USPC 348/836; 361/720; 361/748

(57) ABSTRACT

According to one embodiment, an electronic apparatus includes a board, a first electronic component on the board, a second electronic component on the board, and a fixing member between the first and second electronic components. The second electronic component is designed to produce less heat than the first electronic component. The fixing member is configured to secure the board to a part.

### CROSS-REFERENCE TO RELATED APPLICATIONS

This application is based upon and claims the benefit of priority from Japanese Patent Application No. 2012-099182, filed Apr. 24, 2012, the entire contents of which are incorporated herein by reference.

### FIELD

Embodiments described herein relate generally to a television reception apparatus, a module, and an electronic apparatus.

### BACKGROUND

A television reception apparatus comprises a board such as a printed circuit board. A plurality of electronic components are mounted on the board. Those electronic components which produce much heat are cooled by means of various elements, such as heat radiation sheets.

Some electronic components mounted on a board may produce different amounts of heat. In some cases, heat may be transferred from electronic components that produce more heat to ones that produce less heat, so that the latter components may become hot.

### BRIEF DESCRIPTION OF THE DRAWINGS

A general architecture that implements the various features of the embodiments will now be described with reference to the drawings. The drawings and the associated descriptions are provided to illustrate the embodiments and not to limit the scope of the invention.

FIG. 1 is an exemplary perspective view showing a television according to a first embodiment;

FIG. 2 is an exemplary plan view showing a module in a housing of the first embodiment;

FIG. 3 is an exemplary sectional view of the module of the first embodiment along line F3-F3 of FIG. 2;

FIG. 4 is an exemplary sectional view showing a module in the housing according to a second embodiment;

FIG. 5 is an exemplary plan view showing a module in the housing according to a third embodiment;

FIG. 6 is an exemplary sectional view of the module of the third embodiment along line F6-F6 of FIG. 5;

FIG. 7 is an exemplary sectional view of the module of the third embodiment along line F7-F7 of FIG. 5;

FIG. 8 is an exemplary plan view showing a module in the housing according to a fourth embodiment;

FIG. 9 is an exemplary sectional view of the module of the fourth embodiment along line F9-F9 of FIG. 8;

FIG. 10 is an exemplary plan view showing a module in the housing according to a fifth embodiment;

FIG. 11 is an exemplary sectional view of the module of the fifth embodiment along line F11-F11 of FIG. 10; and

FIG. 12 is an exemplary cutaway perspective view of a portable computer according to a sixth embodiment.

### DETAILED DESCRIPTION

Various embodiments will be described hereinafter with reference to the accompanying drawings.

In general, according to one embodiment, an electronic apparatus includes a board, a first electronic component on the board, a second electronic component on the board, and a fixing member between the first and second electronic components. The second electronic component is designed to produce less heat than the first electronic component. The fixing member is configured to secure the board to a part.

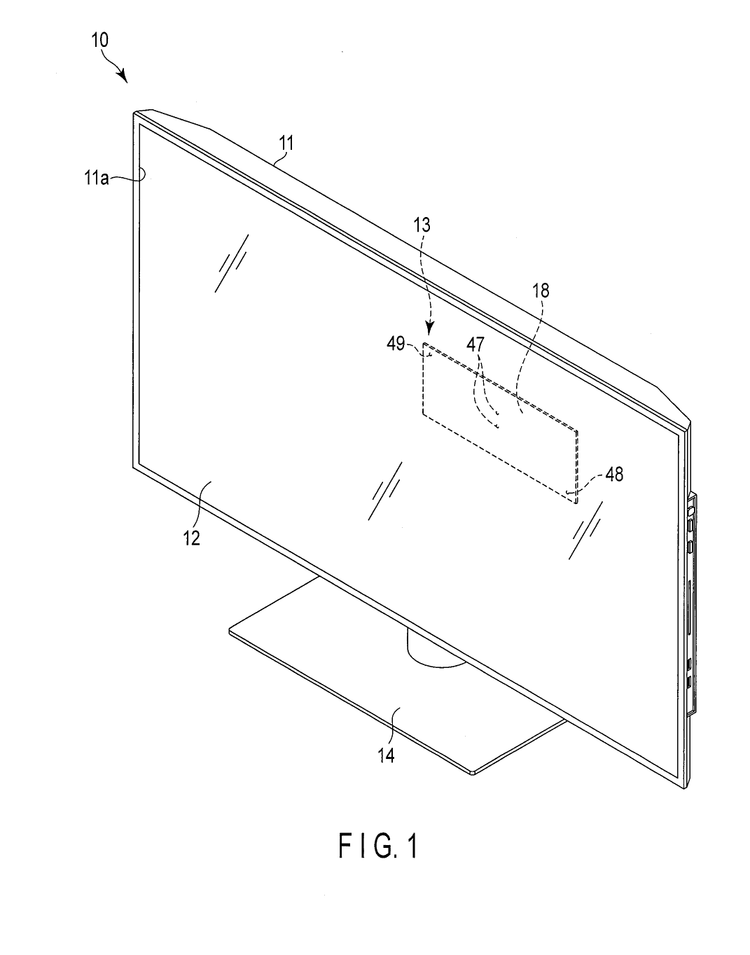

A first embodiment will now be described with reference to FIGS. 1 to 3. In this specification, the near or user side is defined as forward; the far side from the user as rearward, the user's left-hand side as leftward, the user's right-hand side as rightward, the upper side with respect to the user as upward, and the lower side with respect to the user as downward. Further, each element that can be expressed in different ways may sometimes be represented by one or more alternative examples of expressions. However, this neither denies that an element that is not given any alternative expression can be differently expressed, nor restricts other expressions that are not exemplified.

FIG. 1 is an exemplary perspective view of a television reception apparatus (television) 10 according to the first embodiment. The television 10 is an example of electronic apparatus. As shown in FIG. 1, the television 10 comprises a housing 11, display part 12, module 13, and pedestal stand 14. The module 13 can be alternatively expressed as, for example, a part, circuit board, or unit.

The housing 11 is a flat box of, for example, a resin. The housing 11 accommodates the display part 12 and module 13. A display opening 11a is disposed in the front of the housing 11. The display part 12 is exposed from the display opening 11a.

The display part 12 is, for example, a liquid-crystal display (LCD). The display part is not limited to this and may be one of various other parts that can display images, such as a plasma display, organic electroluminescent (EL) display, etc. The display part 12 displays an image on its screen that is exposed from the display opening 11a of the housing 11. In this specification, “images” include still and moving images.

The pedestal stand 14 is attached to the back of the housing 11 and supports the housing 11 at a predetermined height. The housing 11 supported by the pedestal stand 14 is pivotable within a predetermined angular range.

The module 13 processes, for example, image data displayed by the display part 12. The module 13 comprises a board 18. The board 18 can be alternatively expressed as a wiring board, circuit board, or part.

The board 18 is a rectangular, rigid printed circuit board. The board is not limited to this and may be of some other type, such as a flexible printed circuit board. The coefficient of thermal conductivity of the board 18 ranges, for example, from 0.4 to 0.8 W/m·K. The board 18 is connected to, for example, the display part 12 by a cable or some other part.

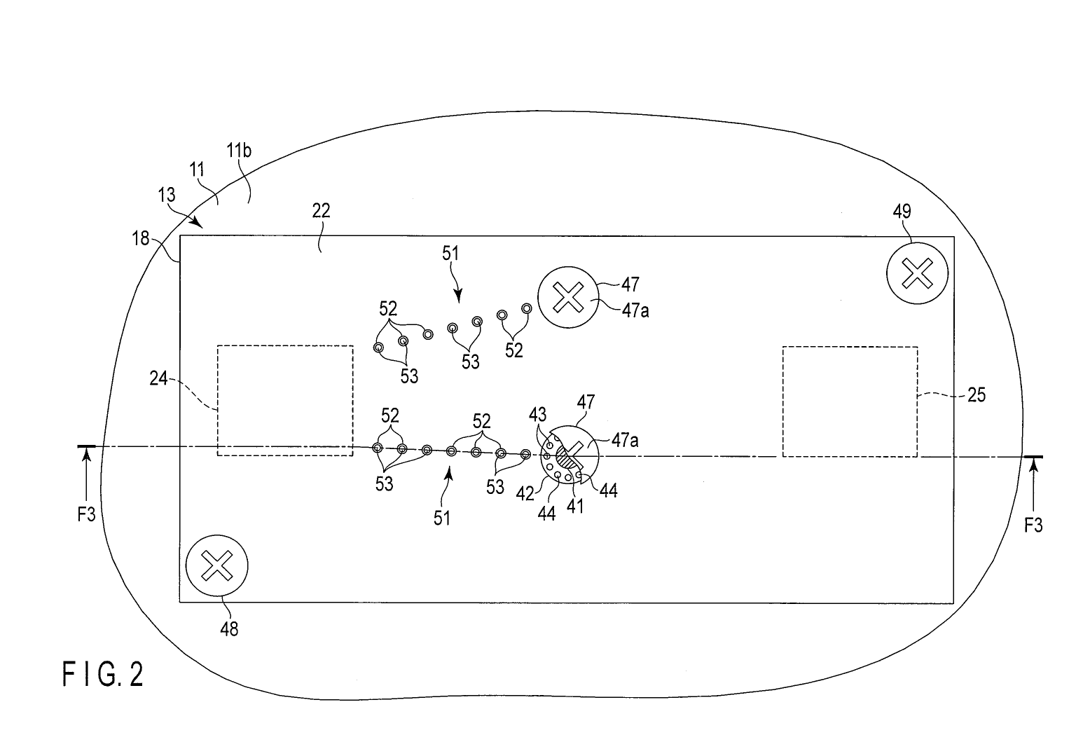

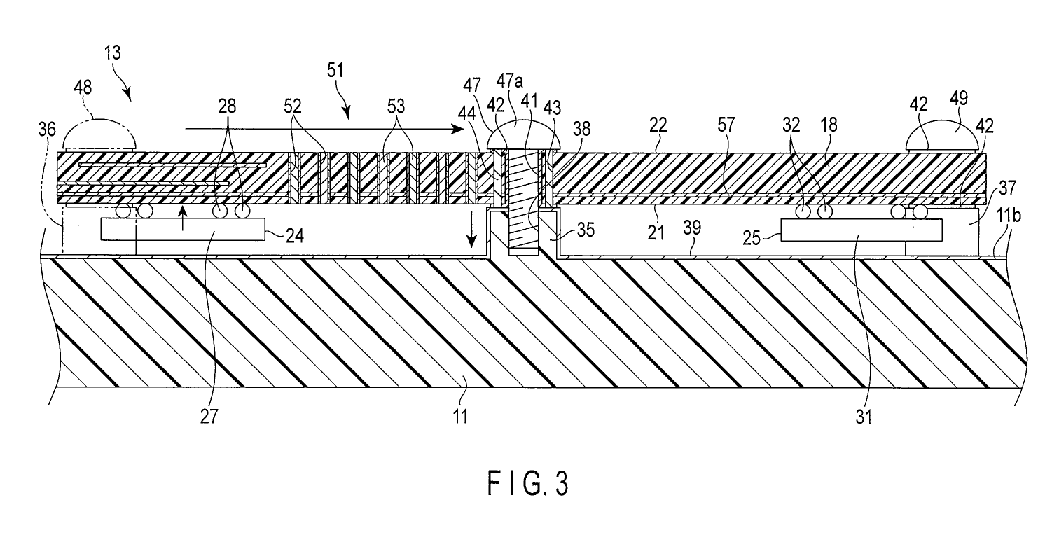

FIG. 2 is an exemplary plan view showing the module 13 in the housing 11. FIG. 3 is an exemplary sectional view of the module 13 along line F3-F3 of FIG. 2. As shown in FIG. 3, the board 18 comprises a first surface 21 and second surface 22. The first surface 21 is an example of that surface of the board opposite the housing 11 and faces an inner surface 11b of the housing 11. The second surface 22 is located opposite the first surface 21. Thus, the second surface 22 faces inwardly relative to the housing 11.

A first electronic component 24, second electronic component 25, and various other electronic components, such as a capacitor, are mounted on the first surface 21. Various electronic components may be mounted on the second surface 22.

The first electronic component 24 is, for example, a ball grid array (BGA). The first electronic component 24 is located, for example, on one end portion of the rectangular board 18. However, it may be located in another position on the board 18.

The second electronic component 25 is, for example, a BGA. The second electronic component 25 is located, for example, on the other end portion of the rectangular board 18. However, it may be located in another position on the board 18.

The first electronic component 24 comprises a first base 27 and a plurality of first terminals 28. The first base 27 is, for example, a board which a part is mounted on, and which is covered by a molded resin. The first terminals 28 are, for example, solder balls, which are arranged in a matrix on the bottom surface of the first base 27. The first terminals 28 are bonded individually to electrodes on the first surface 21 of the board 18.

The second electronic component 25 comprises a second base 31 and a plurality of second terminals 32. The second base 31 is, for example, a board which a part is mounted on, and which is covered by a molded resin. The second terminals 32 are, for example, solder balls, which are arranged in a matrix on the bottom surface of the second base 31. The second terminals 32 are bonded individually to electrodes on the first surface 21 of the board 18.

The second electronic component 25 produces less heat than the first electronic component 24. Specifically, the rate of heat release (per unit time) of the second electronic component 25 is lower than that of the first electronic component 24.

A plurality of bosses 35, 36 and 37 protrude from the inner surface lib of the housing 11. The bosses 35 are located corresponding to a central portion of the board 18. The bosses 36 and 37 are located corresponding individually to corner portions of the board 18. Each of the bosses 35 to 37 is formed with a threaded hole 38.

The inner surface 11b of the housing 11 comprising the bosses 35 to 37 is covered by a metal film 39. The metal film 39 is a copper thin film formed on the inner surface 11b of the housing 11 by, for example, plating. The metal film 39 may be formed from another metal, such as nickel. The coefficient of thermal conductivity of the metal film 39 ranges, for example, from 350 to 400 W/m·K. The housing 11 covered by the metal film 39 is higher in thermal conductivity than the board 18.

The board 18 is formed with a plurality of insertion holes 41, which are an example of a fixed portion. The insertion holes 41 open in positions corresponding individually to the threaded holes 38 for the bosses 35 to 37. Thus, the insertion holes 41 are disposed individually at the central and corner portions of the board 18. The insertion holes 41 at the central portion of the board 18 are located between the first and second electronic components 24 and 25. The insertion holes 41 corresponding to the bosses 36 are located nearer to the first electronic component 24 than to the second electronic component 25. And, the insertion holes 41 corresponding to the bosses 36 are located farther from the second electronic component 25 than from the first electronic component 24.

Receiving portions 42 (for example, circular) are disposed around each of the insertion holes 41. The receiving portions 42 are copper thin films formed around each insertion hole 41 in the first and second surfaces 21 and 22, individually. The receiving portions 42 may be formed from another metal, such as nickel. The coefficient of thermal conductivity of the receiving portions 42 ranges, for example, from 350 to 400 W/m·K. Thus, the receiving portions 42 are higher in thermal conductivity than the board 18.

The receiving portions 42 in the first and second surfaces 21 and 22 are connected to each other by the insertion hole 41. Thus, the metal films that form the receiving portions 42 cover the inner surface of the insertion hole 41.

As shown in FIG. 2, each receiving portion 42 is formed with a plurality of holes 43. The holes 43 are formed ranging from the receiving portion 42 in the first surface 21 to that in the second surface 22.

Each of the holes 43 is filled with a first solder bead 44. The first solder bead 44 is an example of a second heat transfer material. The coefficient of thermal conductivity of the first solder bead 44 ranges, for example, from 50 to 60 W/m·K. Thus, the first solder bead 44 is higher in thermal conductivity than the board 18. The first solder bead 44 may be replaced with various other heat transfer materials, such as a silver paste, copper, resin containing a metal filler, etc.

The first solder bead 44 is formed from, for example, a solder paste. The solder paste is divided so that it corresponds to the individual holes 43 and is applied to the receiving portions 42. The holes 43 are filled with the first solder beads 44 as the solder paste is melted.

As shown in FIG. 3, the first solder bead 44 closely adheres to the inner surface of each hole 43. A part of the first solder bead 44 slightly projects from the receiving portion 42. Alternatively, the entire first solder bead 44 may be accommodated in the hole 43.

A plurality of fixing members 47, 48 and 49 are inserted into the insertion holes 41, individually. Each fixing member 47 is an example of a first fixing member and also an example of a member configured to secure the board to another part. One of the fixing members 48 is an example of a second fixing member.

For example, the fixing members 47 to 49 are screws. The fixing members 47 to 49 are formed from, for example, a metal such as iron. The coefficient of thermal conductivity of the fixing members 47 to 49 ranges, for example, from 80 to 100 W/m·K. Thus, the fixing members 47 to 49 are higher in thermal conductivity than the board 18. The fixing members 47 to 49 are not limited to this configuration and may be various other members, such as protrusions, keys, etc.

Each fixing member 47 is screwed into the threaded hole 38 of its corresponding boss 35 through the insertion hole 41. Specifically, the fixing members 47 are attached to the insertion holes 41 that are located between the first and second electronic components 24 and 25.

A screw head 47a, a part of each fixing member 47, abuts the receiving portion 42 in the second surface 22 of the board 18 and/or a part of the first solder bead 44 projecting from the receiving portion 42. The screw head 47a presses the board 18 toward the boss 35. Accordingly, the metal film 39 on the boss 35 abuts the receiving portion 42 in the first surface 21 of the board 18 and/or a part of the first solder bead 44 projecting from the receiving portion 42.

Likewise, the fixing members 48 and 49 are screwed individually into the respective threaded holes 38 of the bosses 36 and 37. Specifically, one of the fixing member 48 is located nearer to the first electronic component 24 than to the second electronic component 25. The fixing members 47 to 49 secure the board 18 to the bosses 35 to 37 of the housing 11, which is a separate part.

As shown in FIG. 2, the board 18 comprises two first thermal transfer units 51. The first thermal transfer units 51 are disposed individually between the first electronic component 24 and two fixing members 47. Each first thermal transfer unit 51 comprises a plurality of through-holes 52.

The through-holes 52 in the board 18 are arranged from the first electronic component 24 toward their corresponding fixing members 47. As shown in FIG. 3, the through-holes 52 extend from the first surface 21 to the second surface 22 of the board 18. The inner surface of each through-hole 52 is covered by a film of a metal, such as copper. The coefficient of thermal conductivity of this metal film ranges, for example, from 350 to 400 W/m·K. The first thermal transfer unit 51, which comprises the through-holes 52 covered by the metal film, is higher in thermal conductivity than the board 18.

The through-holes 52 are filled with second solder beads 53, individually. Each second solder bead 53 is an example of a first heat transfer material. The coefficient of thermal conductivity of the second solder beads 53 ranges, for example, from 50 to 60 W/m·K. Thus, the second solder beads 53 are higher in thermal conductivity than the board 18. The second solder beads 53 may be replaced with various other thermally conductive materials, such as a silver paste, copper, resin containing a metal filler, etc.

The board 18 comprises a ground layer 57. The board 18 is formed by laminating a plurality of electrically conductive layers, such as the ground layer 57, and a plurality of insulating layers. The through-holes 52 are connected to the ground layer 57. Alternatively, the through-holes 52 may be connected to traces on the board 18. Thus, the through-holes 52 may either be a part of a circuit on the board 18 or be independent of the circuit.

As indicated by an arrow in FIG. 3, heat produced by the first electronic component 24 is first transmitted to the board 18. This heat is transmitted to the first thermal transfer unit 51 that is higher in thermal conductivity than the board 18. Thus, the heat transmitted to the board 18 is directed toward the fixing members 47 through the through-holes 52 and second solder beads 53 which are aligned.

The heat transferred through the first thermal transfer unit 51 is transmitted to the fixing members 47 through the receiving portions 42 in the second surface 22 and/or the first solder beads 44 in the holes 43. The heat transmitted to the fixing members 47 is transferred to the bosses 35 of the housing 11 into which the fixing members 47 are screwed. In this way, the heat produced by the first electronic component 24 is transmitted to the housing 11.

Further, the heat transferred through the first thermal transfer unit 51 is transmitted to the metal film 39 on the bosses 35 of the housing 11 through the receiving portions 42 in the first surface 21 and/or the first solder beads 44 in the holes 43. Thus, the heat produced by the first electronic component 24 is also transmitted through some channel other than the fixing members 47.

Most of the heat produced by the first electronic component 24 is transmitted to the housing 11 through the fixing members 47. Accordingly, heat produced by the first electronic component 24 and transmitted to the second electronic component 25 is less than heat produced by the first electronic component 24 and transmitted to the housing 11.

The coefficient of thermal conductivity of air is, for example, 0.03 W/m·K. Thus, air is lower in thermal conductivity than the board 18. Accordingly, heat transmitted from the first electronic component 24 to the second electronic component 25 through air is less than heat produced by the first electronic component 24 and transmitted to the housing 11.

According to the television 10 constructed in this manner, the fixing members 47 configured to secure the board 18 to the housing 11 are located between the first and second electronic components 24 and 25. Accordingly, heat produced from the first electronic component 24 is transmitted to the housing 11 through the fixing members 47, so that heat transmitted to the second electronic component 25 is reduced. Thus, heat transfer between the first and second electronic components 24 and 25 can be suppressed, so that the second electronic component 25 can be prevented from being damaged by heat transmitted from the first electronic component 24 to the second electronic component 25. Further, the necessity of using such components as heat radiation sheets, radiation fins, etc., is obviated, so that the costs of the television 10 can be reduced. Since the fixing members 47 securely contacts the housing 11, moreover, heat can be reliably transmitted to the housing 11.

The first thermal transfer unit 51 that is higher in thermal conductivity than the board 18 is disposed between the first electronic component 24 and fixing members 47. Accordingly, heat produced by the first electronic component 24 is guided to the first thermal transfer unit 51 and efficiently transmitted to the fixing members 47. Thus, the heat produced by the first electronic component 24 cannot be easily transmitted to the second electronic component 25.

The first thermal transfer unit 51 comprises the plurality of through-holes 52. The through-holes 52 are conventional through-holes that are used in the circuit on the board 18. For example, the through-holes 52 can be used to connect a plurality of traces on the board 18. An increase in cost of the television 10 can be suppressed by transmitting heat through the through-holes 52 arranged in this manner. The through-holes 52 may be different from conventional ones.

The through-holes 52 are filled with the second solder beads 53. The through-holes 52 are higher in thermal conductivity when they are filled with the second solder beads 53 than when they are vacant. Accordingly, the thermal conductivity of the through-holes 52 is increased, so that heat produced by the first electronic component 24 can be efficiently transmitted to fixing members 47.

Each second solder bead 53 is a conventional one that is used in the circuit on the board 18. For example, solder beads of the same type as the second solder beads 53 can be used to mount various electronic components on the board 18. An increase in cost of the television 10 can be suppressed by improving the thermal conductivity of the through-holes 52 by means of the second solder beads 53. The second solder beads 53 may be different from conventional ones.

The through-holes 52 are connected to the ground layer 57, that is, they are individually grounded. Thus, production of noise by the through-holes 52 can be suppressed.

The holes 43 are arranged around the insertion holes 41 into which the fixing members 47 are inserted. Each fixing member 47 is partially in contact with the first solder bead 44 in each hole 43. Even if the fixing member 47 is inclined as it is inserted into the insertion hole 41, therefore, its screw head 47a can easily contact the first solder bead 44. In other words, the fixing members 47 and board 18 can be prevented from losing contact, so that degradation of heat transfer properties can be suppressed. Further, heat transferred to the board 18 can be efficiently transmitted to the fixing members 47 through the first solder beads 44. Since the holes 43 are arranged around each insertion hole 41, moreover, heat transferred to the first thermal transfer units 51 can be easily transmitted to the fixing members 47 in the insertion holes 41.

The inner surface 11b of the housing 11 is covered by the metal film 39. Thus, heat can be easily transmitted from the fixing members 47 and the receiving portions 42 and/or first solder beads 44 to the housing 11. Further, leakage of noise to the outside of the housing 11 can be suppressed. The housing 11 may be formed from a metal such as magnesium alloy. In this case, heat produced from the first electronic component 24 can be more easily transmitted to the housing 11. Furthermore, the inner surface 11b of the resin housing 11 may be exposed.

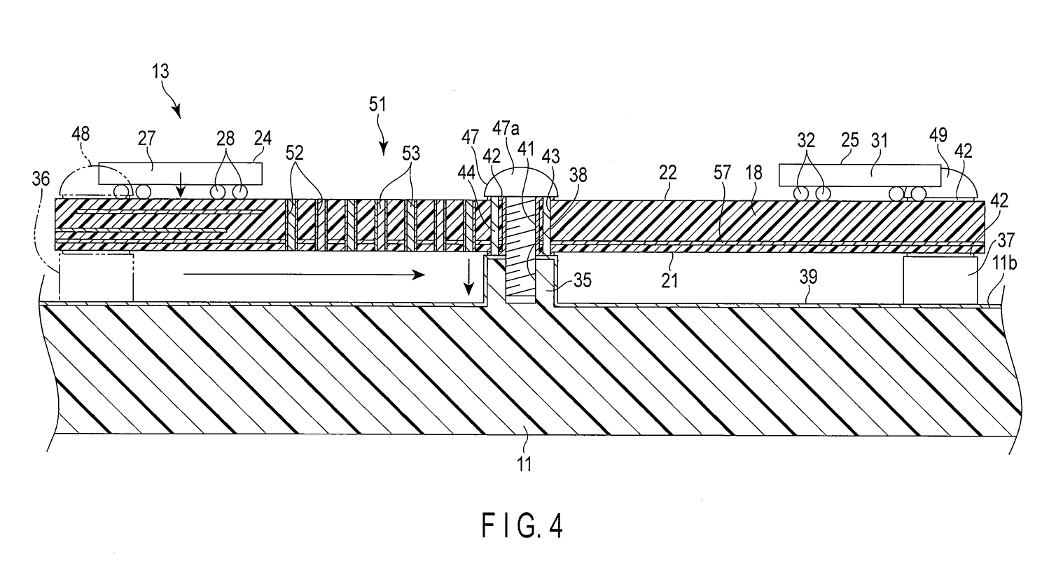

A second embodiment will now be described with reference to FIG. 4. In the description of at least one of the embodiments to follow, like reference numbers are used to designate like constituent parts having the same functions as those of the television 10 of the first embodiment. Further, a description of those constituent parts may be partially or entirely omitted.

FIG. 4 is an exemplary sectional view showing a module 13 in a housing 11 according to the second embodiment. As shown in FIG. 4, a first electronic component 24 and second electronic component 25 are mounted on a second surface 22 of a board 18. Also in a television 10 constructed in this manner, as in the first embodiment, heat produced by the first electronic component 24 is transmitted to the housing 11 through fixing members 47. Thus, heat transfer between the first and second electronic components 24 and 25 can be suppressed, so that the second electronic component 25 can be prevented from being damaged by heat transmitted from the first electronic component 24 to the second electronic component 25.

Also in the case where the first and second electronic components 24 and 25 are disposed on the second surface 22 of the board 18, as described above, heat transfer between the electronic components 24 and 25 can be suppressed. Thus, the electronic components 24 and 25 may be mounted in any position on the board 18. Further, the first and second electronic components 24 and 25 may be mounted individually on different surfaces. In this way, the design flexibility of the television 10 is improved.

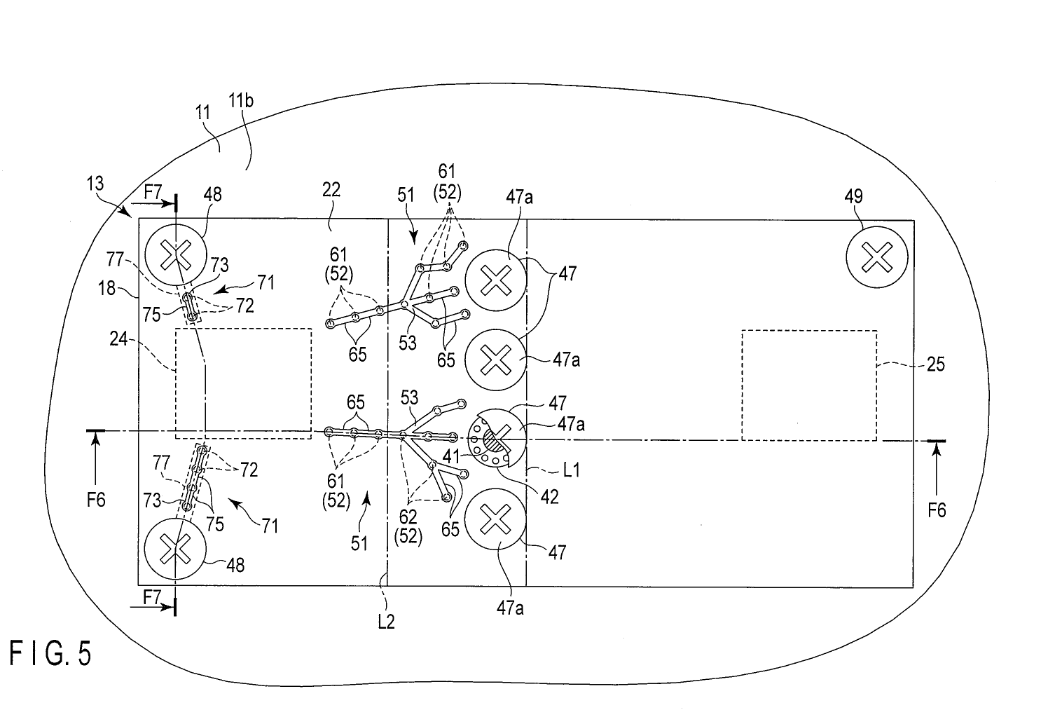

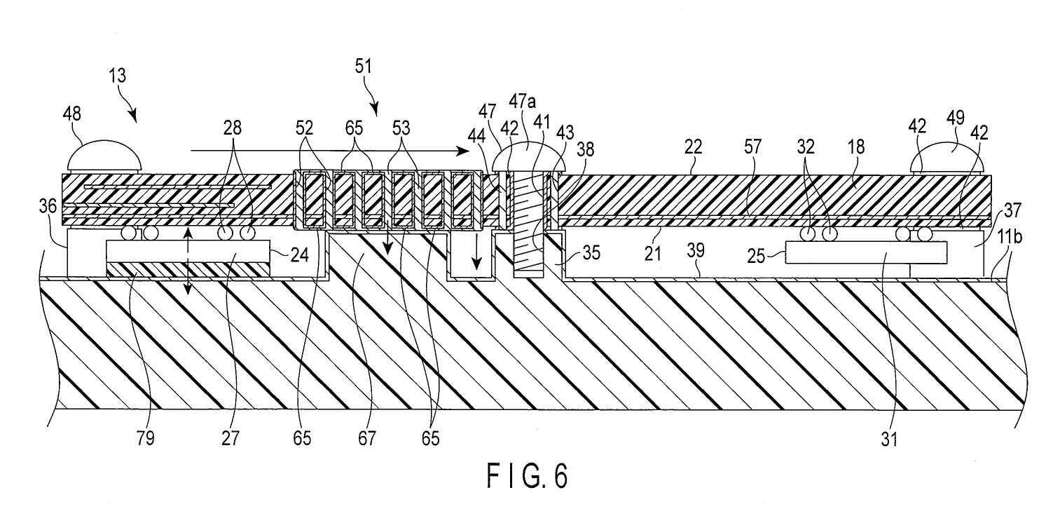

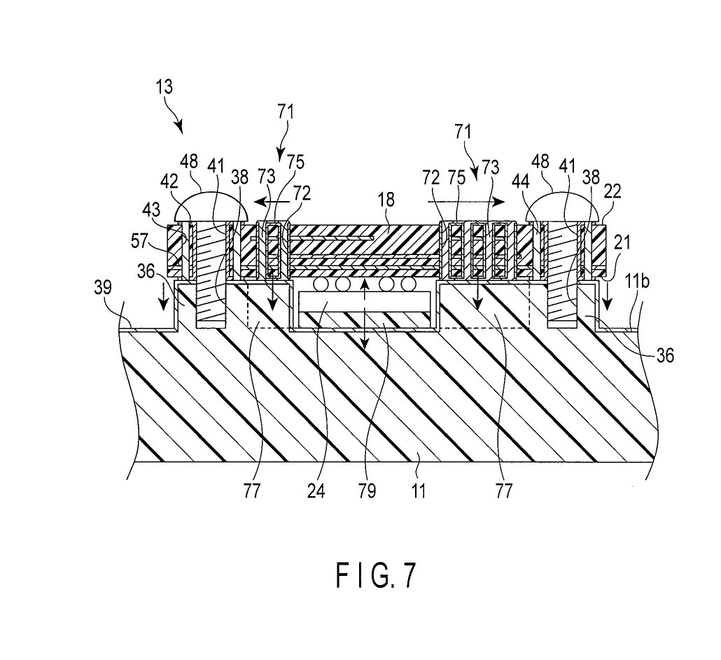

A third embodiment will now be described with reference to FIGS. 5 to 7. FIG. 5 is an exemplary plan view showing a module 13 in a housing 11 according to the third embodiment. FIG. 6 is an exemplary sectional view of the module 13 along line F6-F6 of FIG. 5. FIG. 7 is an exemplary sectional view of the module 13 along line F7-F7 of FIG. 5.

As shown in FIG. 5, fixing members 47 of the third embodiment number more than those of the first embodiment. While the fixing members 47 are arranged in a line, they may be arranged in a different way.

In FIG. 5, a dash-dotted line indicates a first intermediate line L1 in the center between first and second electronic components 24 and 25. Another dash-dotted line indicates a second intermediate line L2 in the center between the first electronic component 24 and fixing members 47. The first and second intermediate lines L1 and L2 are imaginary lines given for ease of illustration.

The fixing members 47 are located nearer to the first electronic component 24 than the first intermediate line L1. In other words, the distance between the first electronic component 24 and fixing members 47 is shorter than that between the second electronic component 25 and fixing members 47. The fixing members 47 may be located partially overlapping the first intermediate line L1.

A plurality of through-holes 52 comprise a plurality of first through-holes 61 and a plurality of second through-holes 62. The first and second through-holes 61 and 62 are identical except for their positions. Alternatively, they may be different in configuration.

The first through-holes 61 are located nearer to the first electronic component 24 than the second intermediate line L2. In other words, the first through-holes 61 are located nearer to the first electronic component 24 than the center between the first electronic component 24 and fixing members 47. The first through-holes 61 may be located partially overlapping the second intermediate line L2.

The second through-holes 62 are located nearer to the fixing members 47 than the second intermediate line L2. In other words, the second through-holes 62 are located nearer to the fixing members 47 than the center between the first electronic component 24 and fixing members 47. The second through-holes 62 may be located partially overlapping the second intermediate line L2. The second through-holes 62 number more than the first through-holes 61.

The second through-holes 62 increase in number as the distance from the fixing members 47 decreases. In other words, the second through-holes 62 nearer to the fixing members 47 number more than those farther from the fixing members 47.

As shown in FIG. 6, a first thermal transfer unit 51 comprises a plurality of first junctions 65. The first junctions 65 are patterns that are formed from, for example, copper and connect the through-holes 52. The coefficient of thermal conductivity of the first junctions 65 ranges, for example, from 350 to 400 W/m·K. Thus, the first junctions 65 are higher in thermal conductivity than a board 18. The first junctions 65 are disposed on each of first and second surfaces 21 and 22 of the board 18.

As shown in FIG. 5, the second through-holes 62 are arranged in a plurality of lines. The second through-holes 62 and first junctions 65 form branched channels.

As shown in FIG. 6, second solder beads 53 adhere to the first junctions 65. Thus, the second solder beads 53 that fill the through-holes 52 are continuously connected to one another by the second solder beads 53 that adhere to the first junctions 65. In other words, the second solder beads 53 in the through-holes 52 are integral.

The second solder beads 53 that fill the through-holes 52 are thermally connected to one another by the first junctions 65 and some of the second solder beads 53 that adhere to the first junctions 65. Alternatively, the second solder beads 53 may be thermally connected to one another by other members, such as wires.

The housing 11 comprises a contact portion 67, which projects from an inner surface 11b of the housing 11 and is covered by a metal film 39. The contact portion 67 is in contact with the second solder beads 53 that adhere to the first junctions 65. Thus, the first thermal transfer unit 51 is in contact with the housing 11. Another portion of the first thermal transfer unit 51 may be designed to contact another portion of the housing 11.

As shown in FIG. 7, two fixing members 48 are attached to the board 18. The fixing members 48 are screwed individually into respective threaded holes 38 of two bosses 36, thereby securing the board 18 to the housing 11. The bosses 36 and fixing members 48 are not limited to this number.

The board 18 comprises a plurality of second thermal transfer units 71, which are located individually between the first electronic component 24 and fixing members 48. Each of the second thermal transfer units 71 comprises a plurality of third through-holes 72.

As shown in FIG. 5, the third through-holes 72 in the board 18 are arranged from the first electronic component 24 toward their corresponding fixing members 48. As shown in FIG. 7, the third through-holes 72 extend from the first surface 21 to the second surface 22 of the board 18.

The inner surface of each third through-hole 72 is covered by a film of a metal, such as copper. The coefficient of thermal conductivity of this metal film ranges, for example, from 350 to 400 W/m·K. The first thermal transfer unit 51, which comprises the third through-holes 72 covered by the metal film, is higher in thermal conductivity than the board 18.

The third through-holes 72 are filled with third solder beads 73, individually. The coefficient of thermal conductivity of the third solder beads 73 ranges, for example, from 50 to 60 W/m·K. Thus, the third solder beads 73 are higher in thermal conductivity than the board 18. The third solder beads 73 may be replaced with various other heat transfer materials, such as a silver paste, copper, resin containing a metal filler, etc.

The third through-holes 72 are connected to a ground layer 57. Alternatively, the third through-holes 72 may be connected to traces on the board 18. Thus, the third through-holes 72 may either be a part of a circuit on the board 18 or be independent of the circuit.

The second thermal transfer units 71 comprise a plurality of second junctions 75. The second junctions 75 are patterns that are formed from, for example, copper and connect the third through-holes 72. The coefficient of thermal conductivity of the second junctions 75 ranges, for example, from 350 to 400 W/m·K. Thus, the second junctions 75 are higher in thermal conductivity than the board 18. The second junctions 75 are disposed on each of the first and second surfaces 21 and 22 of the board 18.

The third solder beads 73 adhere to the second junctions 75. Thus, the third solder beads 73 that fill the third through-holes 72 are continuously connected to one another by the third solder beads 73 that adhere to the second junctions 75. In other words, the third solder beads 73 in the third through-holes 72 are integral.

The third solder beads 73 that fill the third through-holes 72 are thermally connected to one another by the second junctions 75 and some of the third solder beads 73 that adhere to the second junctions 75. Alternatively, the third solder beads 73 may be thermally connected to one another by other members, such as wires.

Each of the bosses 36 comprises a rib 77. The rib 77 extends from the boss 36 and is covered by the metal film 39. The ribs 77 are in contact with the third solder beads 73 that adhere to the second junctions 75. Thus, the second thermal transfer units 71 are in contact with the ribs 77 of the housing 11. Other portions of the second thermal transfer units 71 may be designed to contact other portions of the housing 11.

A heat radiation sheet 79 is affixed to the first electronic component 24. The heat radiation sheet 79 is an example of a heat radiation member. The heat radiation sheet 79 is formed from, for example, a resin that is higher in thermal conductivity than the board 18. The heat radiation sheet 79 may be formed from another material, such as a metal.

The heat radiation sheet 79 is in contact with the inner surface lib of the housing 11 covered by the metal film 39, as well as with the first electronic component 24. In other words, the heat radiation sheet 79 is sandwiched between the first electronic component 24 and the inner surface 11b of the housing 11.

As shown in FIG. 6, heat produced by the first electronic component 24 is first transmitted to the board 18. This heat is transmitted to the first thermal transfer unit 51 that is higher in thermal conductivity than the board 18. Thus, the heat transmitted to the board 18 is directed toward the fixing members 47 through the through-holes 52 connected by the first junctions 65 and the integral second solder beads 53. The heat transmitted through the first thermal transfer unit 51 is transmitted to the housing 11 through the fixing member 47.

Further, the heat transferred through the first thermal transfer unit 51 is transmitted to the contact portion 67 in contact with the first thermal transfer unit 51. Thus, the heat produced by the first electronic component 24 is transmitted to the contact portion 67 of the housing 11 before it is transmitted to the fixing members 47.

As shown in FIG. 7, heat transferred to the board 18 is transmitted to the second thermal transfer units 71 that are higher in thermal conductivity than the board 18. Specifically, the heat transmitted to the board 18 is directed toward the fixing members 48 through the third through-holes 72 connected by the second junctions 75 and the integral third solder beads 73. The heat transferred through the second thermal transfer units 71 is transmitted to the housing 11 through the fixing members 48. Thus, the heat produced by the first electronic component 24 is transmitted to the housing 11 through the fixing members 48 that are located nearer to the first electronic component 24 than to the second electronic component 25.

Further, the heat transferred through the second thermal transfer units 71 is transmitted to the ribs 77 in contact with the second thermal transfer units 71. Thus, the heat produced by the first electronic component 24 is transmitted to the ribs 77 of the housing 11 before it is transmitted to the fixing members 48.

In addition, the heat produced by the first electronic component 24 is transmitted to the housing 11 through the heat radiation sheet 79. Thus, the heat produced by the first electronic component 24 is also transmitted through a plurality of channels other than the fixing members 47.

Most of the heat produced by the first electronic component 24 is transmitted to the housing 11 through the fixing members 47 and 48 and heat radiation sheet 79. Accordingly, heat produced by the first electronic component 24 and transmitted to the second electronic component 25 is less than heat produced by the first electronic component 24 and transmitted to the housing 11.

According to a television 10 constructed in this manner, the distance between the first electronic component 24 and fixing members 47 is shorter than that between the second electronic component 25 and fixing members 47. In other words, the fixing members 47 that absorb heat produced by the first electronic component 24 are located far from the second electronic component 25. Thus, the heat produced by the first electronic component 24 cannot be easily transmitted to the second electronic component 25.

In some cases, a large number of traces may be formed near the first electronic component 24. The second through-holes 62 farther from the first electronic component 24 number more than the first through-holes 61 nearer to the first electronic component 24. Thus, restrictions on the arrangement of the traces around the first electronic component 24 can be suppressed. Since, moreover, the second through-holes 62 near the fixing members 47 number more, heat produced by the first electronic component 24 can be more easily transmitted to the fixing members 47.

The second solder beads 53 that fill the through-holes 52 are thermally connected to one another. Thus, heat produced by the first electronic component 24 can be efficiently transferred between the through-holes 52 that are filled with the second solder beads 53.

The first thermal transfer unit 51 comprises the first junctions 65 that connect the through-holes 52. Thus, heat produced by the first electronic component 24 can be efficiently transferred between the through-holes 52.

The second solder beads 53 that fill the through-holes 52 adhere to the first junctions 65 and continuously connect one another. These second solder beads 53 are formed from, for example, a solder paste that is collectively applied to the through-holes 52. Specifically, the solder paste is applied to the through-holes 52 that are connected by the first junctions 65, and the solder paste is melted. The molten solder paste forms the second solder beads 53 that fill the through-holes 52 and adhere to the first junctions 65. In this way, the second solder beads 53 can be easily formed. Further, heat produced by the first electronic component 24 is transmitted to the integral second solder beads 53. Thus, the heat produced by the first electronic component 24 can be easily transferred through the first thermal transfer units 51.

The contact portion 67 of the housing 11 is in contact with the first thermal transfer unit 51. Thus, the heat produced by the first electronic component 24 is transmitted to the housing 11 through the first thermal transfer unit 51, so that it can be less easily transmitted to the second electronic component 25.

The second thermal transfer units 71 are disposed between the first electronic component 24 and fixing members 48. Accordingly, heat produced by the first electronic component 24 is transmitted to the housing 11 through the fixing members 48, as well as through the fixing members 47. Thus, the heat produced by the first electronic component 24 can be less easily transmitted to the second electronic component 25.

The heat radiation sheet 79 is sandwiched between the first electronic component 24 and housing 11. Accordingly, heat produced by the first electronic component 24 is transmitted to the housing 11 through the heat radiation sheet 79. Thus, the heat produced by the first electronic component 24 can be less easily transmitted to the second electronic component 25.

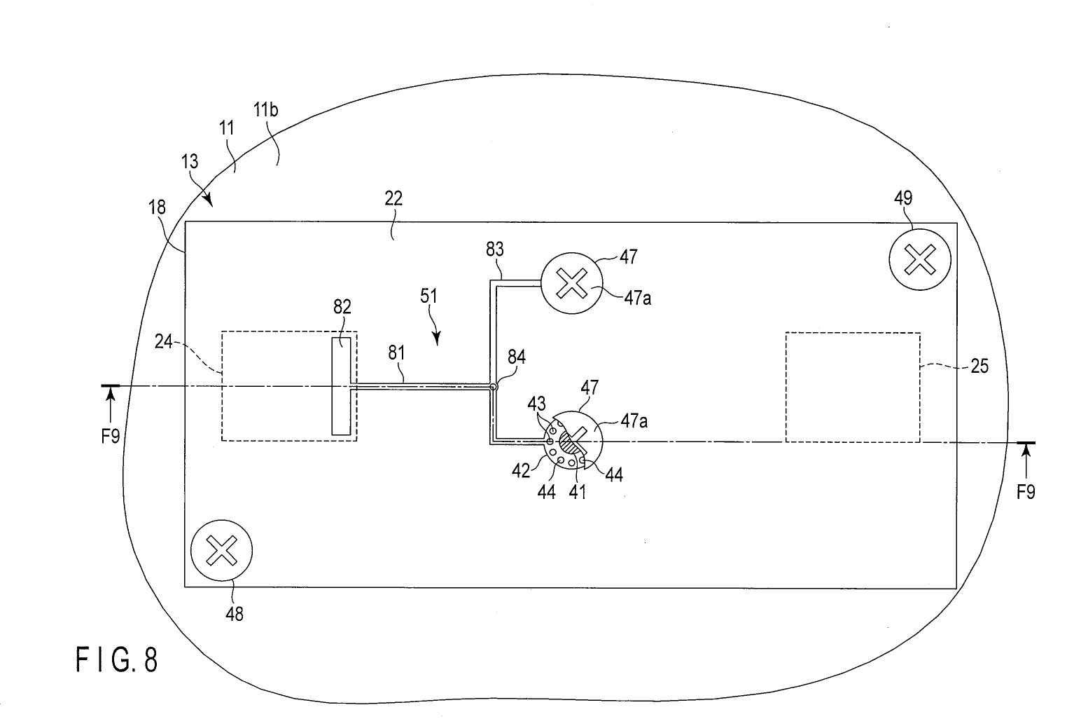

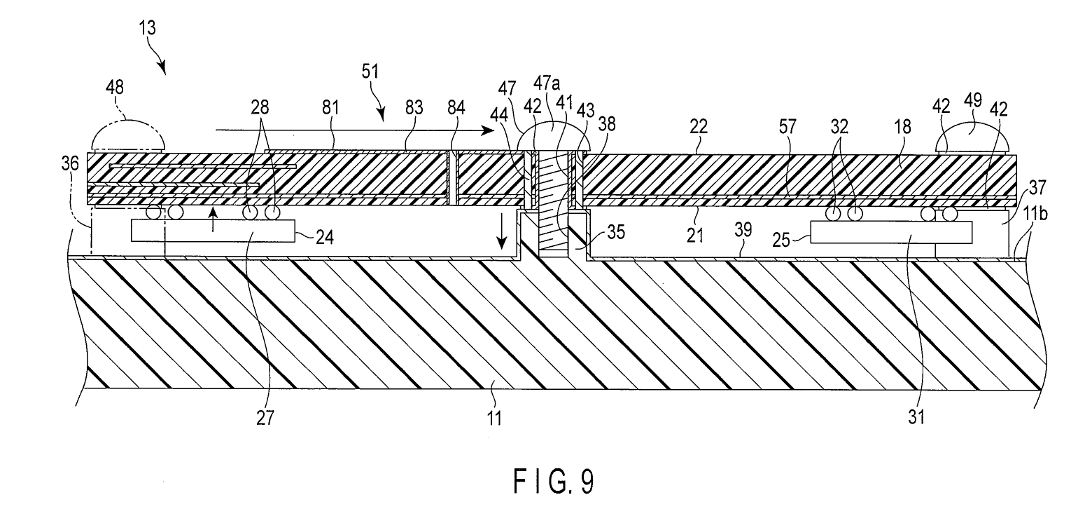

A fourth embodiment will now be described with reference to FIGS. 8 and 9. FIG. 8 is an exemplary plan view showing a module 13 in a housing 11 according to the fourth embodiment. FIG. 9 is an exemplary sectional view of the module 13 along line F9-F9 of FIG. 8.

As shown in FIG. 8, a first thermal transfer unit 51 comprises a dummy pattern 81 in place of the through-holes 52. The dummy pattern 81 is an example of a pattern. The dummy pattern 81, like a conventional trace that forms a circuit on a board 18, is formed from, for example, a copper thin film. The dummy pattern 81 may be formed from another metal, such as nickel.

The dummy pattern 81 is disposed on a second surface 22 of the board 18. The dummy pattern 81 comprises a heat receiving portion 82, conductor portion 83, and via-hole 84. The heat receiving portion 82 and conductor portion 83 are formed integrally with each other.

The heat receiving portion 82 is a rectangular element disposed in such a position that it at least partially overlaps a first electronic component 24. The heat receiving portion 82 may be formed into another shape or disposed near the first electronic component 24.

The conductor portion 83 extends from the heat receiving portion 82 to receiving portions 42, which overlap fixing members 47. The conductor portion 83 may be designed to extend to the vicinity of the receiving portions 42. In other words, the conductor portion 83 is disposed between the first electronic component 24 and fixing members 47. The conductor portion 83 is connected to the receiving portions 42. The conductor portion 83 may be designed to form a channel branched in the middle, as shown in FIG. 8, or to form separate channels that extend to the receiving portions 42.

As shown in FIG. 9, the via-hole 84 is disposed extending from a first surface 21 to the second surface 22 of the board 18. The via-hole 84 electrically connects the conductor portion 83 and a ground layer 57. The dummy pattern 81 is grounded to the ground layer 57 by the via-hole 84.

According to a television 10 constructed in this manner, heat produced by the first electronic component 24 is transmitted to the fixing members 47 through the dummy pattern 81. An increase in cost can be suppressed by thus transmitting heat by means of the dummy pattern 81.

The heat receiving portion 82 of the dummy pattern 81 is located overlapping the first electronic component 24. Thus, heat produced by the first electronic component 24 can be efficiently transmitted to the dummy pattern 81.

The conductor portion 83 of the dummy pattern 81 is connected to the receiving portions 42. Thus, the heat transferred to the dummy pattern 81 can be efficiently transmitted to the fixing members 47 through the receiving portions 42 and second solder beads 53.

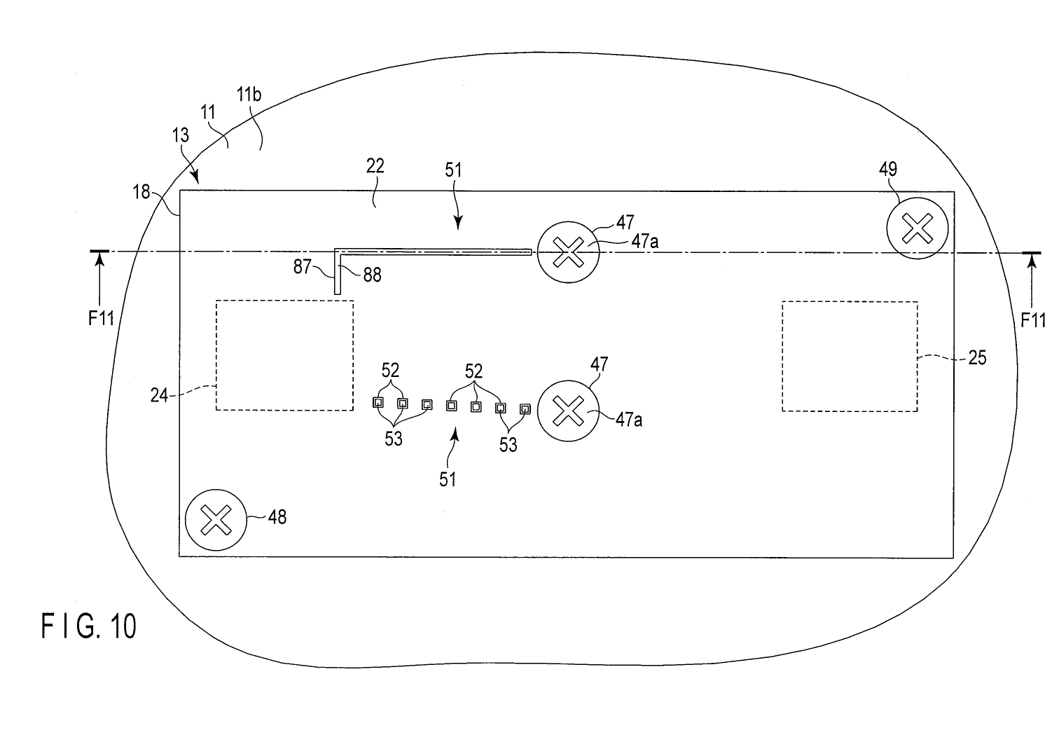

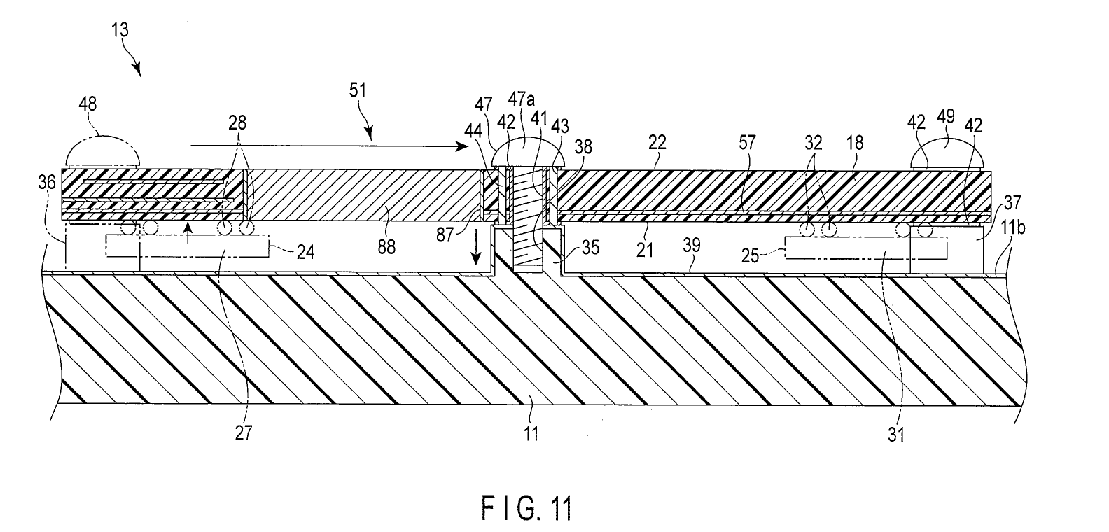

A fifth embodiment will now be described with reference to FIGS. 10 and 11. FIG. 10 is an exemplary plan view showing a module 13 according to the fourth embodiment. FIG. 11 is an exemplary sectional view of the module 13 along line F11-F11 of FIG. 10.

In the fifth embodiment, through-holes 52 of one first thermal transfer unit 51 have such a rectangular shape as shown in FIG. 10. Thus, the shape of the through-holes 52 is not limited to the circular or rectangular one and may be selected from various other shapes.

The other first thermal transfer unit 51 comprises a slit 87 in place of the through-holes 52. The slit 87 extends from the vicinity of a first electronic component 24 to the vicinity of a fixing member 47. As shown in FIG. 11, the slit 87 is disposed extending from a first surface 21 to a second surface 22 of a board 18. The inner surface of the slit 87 is covered by a film of a metal, such as copper.

The slit 87 is filled with a fourth solder bead 88. The coefficient of thermal conductivity of the fourth solder bead 88 ranges, for example, from 50 to 60 W/m·K. Thus, the fourth solder bead 88 is higher in thermal conductivity than the board 18. The fourth solder bead 88 may be replaced with various other heat transfer materials, such as a silver paste, copper, resin containing a metal filler, etc.

According to a television 10 constructed in this manner, heat produced by the first electronic component 24 is transmitted to the fixing member 47 through the slit 87 filled with the fourth solder bead 88. Thus, the first thermal transfer units 51 may comprise various elements, such as the through-holes 52, dummy pattern 81, slit 87, etc. Alternatively, the first thermal transfer units 51 may comprise other parts with high thermal conductivity, such as wires, electronic components, metal blocks, etc.

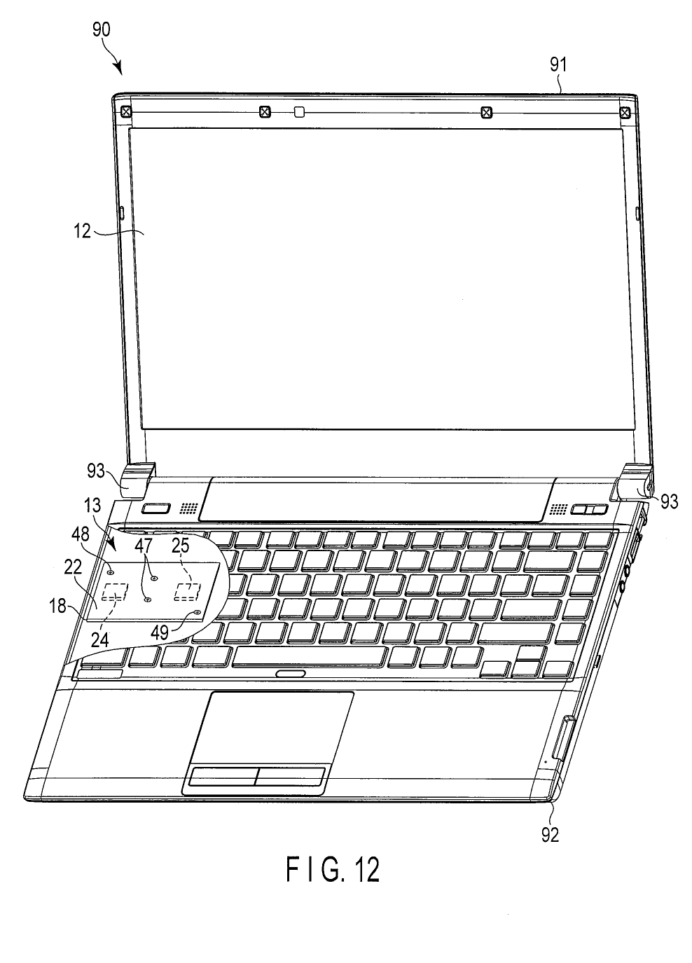

A sixth embodiment will now be described with reference to FIG. 12. FIG. 12 is an exemplary cutaway perspective view of a portable computer 90 according to the sixth embodiment. The portable computer 90 is an example of electronic apparatus.

As shown in FIG. 12, the portable computer 90 comprises a first housing 91 and second housing 92. The second housing 92 is an example of a housing. A pair of hinges 93 are disposed individually at opposite end portions of the first housing 91. The second housing 92 is pivotably connected to the first housing 91 by the hinges 93.

The first and second housings 91 and 92 accommodate a display part 12 and module 13, respectively. As in the first embodiment, the module 13 comprises a board 18.

A first electronic component 24 and second electronic component 25 are mounted on the board 18. Fixing members 47 are disposed between the first and second electronic components 24 and 25. The fixing members 47 secure the board 18 to the second housing 92.

As described above, the electronic apparatus is not limited to the television 10 according to each of the first to fifth embodiments, and may be a portable computer, desktop computer, cellphone, or other electronic apparatus.

According to the television reception apparatus, module, and electronic apparatus described herein, the fixing members configured to secure the board to the housing are disposed between the first and second electronic components. Thus, heat transfer between a plurality of electronic components can be suppressed.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

For example, the housing is not limited to the portion that covers such parts as the display part 12 and board 18. The board 18 may be secured only to a frame or other component that constitutes a part of the housing. Further, the first and second electronic components 24 and 25 are not limited to BGAs and may alternatively be pin grid arrays (PGAs), quad flat packages (QFPs), integrated circuits, and the like.

Furthermore, some of the embodiments may be combined. For example, the heat radiation sheet 79 may be attached to the first electronic component 24 of the fourth embodiment, or the first thermal transfer unit 51 of the third embodiment may be designed to comprise the slit 87 of the fifth embodiment.

What is claimed is:

1. A television reception apparatus comprising:
a housing;
a display in the housing, the display configured to display an image;
a board in the housing;
a first electronic component on the board;
a second electronic component on the board, the second electronic component configured to produce less heat than the first electronic component;
a first fixing member between the first and second electronic components, the first fixing member configured to secure the board to the housing; and
a first thermal transfer unit between the first electronic component and the first fixing member on the board, the first thermal transfer unit higher in thermal conductivity than the board.

2. The television reception apparatus of claim 1, wherein the first thermal transfer unit comprises a plurality of through-holes in the board, and a plurality of first heat transfer materials in the through-holes, the first heat transfer materials higher in thermal conductivity than the board.

3. The television reception apparatus of claim 2, wherein the distance between the first fixing member and the first electronic component is shorter than that of between the first fixing member and the second electronic component.

4. The television reception apparatus of claim 3, wherein
the through-holes comprise a plurality of first through-holes and a plurality of second through holes, the first electronic component is nearer to the plurality of first through-holes than to a center between the first electronic component and the first fixing member, and is nearer to the center between the first electronic component and the first fixing member than to the plurality of second through holes, and
the second through-holes are more than the first through-holes.

5. The television reception apparatus of claim 4, wherein the first heat transfer materials comprise solders.

6. The television reception apparatus of claim 5, wherein the first heat transfer materials are thermally connected to one another.

7. The television reception apparatus of claim 6,
wherein the first heat transfer materials comprise junctions which are higher in thermal conductivity than the board, the junctions connecting the through-holes, and
the first heat transfer materials adhere to the junctions and continuously connect with one another.

8. The television reception apparatus of claim 7, wherein the first heat transfer materials contact the housing.

9. The television reception apparatus of claim 8, wherein the board comprises a ground layer, and
the through-holes are connected to the ground layer.

10. The television reception apparatus of claim 9,
wherein the board comprises an insertion hole into which the first fixing member is inserted, holes around the insertion hole, and a second heat transfer materials in the holes, the second heat transfer materials higher in thermal conductivity than the board, and
the first fixing member partially contacts the second heat transfer materials.

11. The television reception apparatus of claim 10, further comprising
a second fixing member nearer to the first electronic component than to the second electronic component, the second fixing member configured to secure the board to the housing, and
a second thermal transfer unit higher in thermal conductivity than the board, the second thermal transfer unit between the first electronic component and the second fixing member on the board.

12. The television reception apparatus of claim 11, further comprising
a heat radiation member higher in thermal conductivity than the board,
wherein the first electronic component is on a surface of the board facing the housing, and
the heat radiation member is between the first electronic component and the housing.

13. The television reception apparatus of claim 1, wherein the first thermal transfer unit comprises a metal pattern between the first electronic component and the first fixing member.

14. A module comprising:
a board;
a first electronic component on the board; and
a second electronic component on the board, the second electronic component configured to produce less heat than the first electronic component,
wherein the board comprises a fixed portion between the first and second electronic components, the fixed portion configured to be fitted with a member configured to secure the board to a part, and a thermal transfer unit between the first electronic component and the fixed portion, the thermal transfer unit higher in thermal conductivity than the board.

15. An electronic apparatus comprising:
a board;
a first electronic component on the board;
a second electronic component on the board, the second electronic component configured to produce less heat than the first electronic component; and
a fixing member between the first and second electronic components, the fixing member configured to secure the board to a part.
